(19) United States
(12) Patent Application Publication
(10) Pub. No.: US 2008/0041445 A1
(43) Pub. Date: Feb. 21, 2008

(54) ENERGY CAPTURE SYSTEM

(76) Inventors: John J. Miller JR., Sugarcreek, OH (US); Charles R. Brackney III, Baltic, OH (US); Ryan D. Luecke, Sugarcreek, OH (US); Daniel J. Miller, Dover, OH (US)

Correspondence Address: FRASER CLEMENS MARTIN & MILLER LLC, 28366 KENSINGTON LANE, PERRYSBURG, OH, 43551, US

(21) Appl. No.: 11/924,981

(22) Filed: Oct. 26, 2007

Related U.S. Application Data
(63) Continuation-in-part of application No. 11/736,835, filed on Apr. 18, 2007.
(60) Provisional application No. 60/792,842, filed on Apr. 18, 2006.
(60) Provisional application No. 60/792,843, filed on Apr. 18, 2006.
(60) Provisional application No. 60/843,321, filed on Sep. 8, 2006.

(51) Int. Cl. H01L 31/04

(52) U.S. Cl. 136/259

(57) ABSTRACT

A solar panel system is disclosed, wherein energy is captured by the solar panel system and stored for re-use in an energy storage device. The solar panel system facilitates a preservation of aesthetics while a complexity of installation, cost of the solar panel system, and cost of installation are minimized.

### CROSS-REFERENCE TO RELATED APPLICATION

This application is a Continuation-In-Part of U.S. patent application Ser. No. 11/736,835, which claims the benefit of U.S. Prov. Pat. App. Ser. No. 60/792,842 filed Apr. 18, 2006; U.S. Prov. Pat. App. Ser. No. 60/792,843 filed Apr. 18, 2006; and U.S. Prov. Pat. App. Ser. No. 60/843,321 filed Sep. 8, 2006, each of which is incorporated herein by reference in its entirety.

### FIELD OF THE INVENTION

The present invention relates generally to an energy capture system and more particularly to an energy capture system for use with an accessory system, wherein energy for operating the accessory system is captured by a photovoltaic cell and stored for re-use in an energy storage system.

### BACKGROUND OF THE INVENTION

A locking system is used for a variety of applications. The applications may include use in a door for a building, a gate, a vehicle, storage units, and the like. The locking systems provide a means for facilitating controlled access to areas, buildings, rooms, compartments, portable storage devices, tool boxes, and the like. Often, the locking systems are used in locations where electrical power may not be available. These locations include remotely located buildings, remotely located gates, and vehicles, for example.

Where access to the locking system is restricted or limited, it may be desirable to provide a remotely actuated locking system. The remotely actuated locking system facilitates a locking and unlocking of the locking system from a location remote from the locking system. Therefore, in applications where manual actuation of the locking system is not possible, difficult, impractical, or not desirable, the remotely operated locking system provides a convenient method of operating the locking system. However, in locations where electrical power is not available, use of remotely actuated locking systems is hindered.

An accessory system is used in a variety of applications. The applications may include use in a building, a vehicle, and the like. The accessory system provides lighting, locking mechanisms, and the like. Typically, electrical energy for the accessory system is provided from an external source. However, when the accessory system is used in remote locations, electrical energy may not be readily available.

Where access to the accessory system is restricted or limited, it may be desirable to provide a self contained source of electrical energy, such as a battery, for example. The self contained source of electrical energy facilitates operation of the accessory system without reliance on the external source of electrical energy. However, the self contained source of electrical energy typically requires replacement after a period of time.

One use for the accessory system is a remotely operated entry system. A high percentage of vehicles are provided with a remote keyless entry system. Most remote keyless entry systems include an alarm to protect the vehicle against theft, and lock and unlock doors and trunks of the equipped vehicles. Remote keyless entry systems typically consist of a key fob transmitter and an associated receiver inside the vehicle. While remote keyless entry systems have become very popular for use in vehicles, it must be understood that entry systems of buildings, trailers, boats, etc. are likely candidates for such systems as well. Additional uses for the accessory system include signal lighting, general lighting, and cigarette lighter adapters, for example.

There is a need for a self powered accessory system which is self contained, self powered, simple in structure, and may be readily and easily adapted to a wide variety of end uses.

Accordingly, it would be desirable to produce an energy collection system which facilitates a preservation of aesthetics while a complexity of installation, cost of the system, and cost of installation are minimized, and which may be readily and easily adapted to a wide variety of end uses.

### SUMMARY OF THE INVENTION

Consistent and consonant with the present invention, energy collection system which facilitates a preservation of aesthetics while a complexity of installation, cost of the system, and cost of installation are minimized, and which may be readily and easily adapted to a wide variety of end uses, has surprisingly been discovered.

In one embodiment, the energy collection system comprises a main body having a first surface and a second surface; a photovoltaic cell disposed in the main body for capturing light energy, the main body cooperating with the photovoltaic cell to maximize an aesthetic appeal of the energy collection system; and an adhesive material disposed on the second surface of the main body.

In another embodiment, an energy collection system comprises a main body having a first surface and a second surface; a photovoltaic cell disposed in the main body for capturing light energy, the first surface of the main body having at least one window formed therein to minimize a view of the photovoltaic cell and maximize an aesthetic appeal of the energy collection system; and an adhesive material disposed on the second surface of the main body.

In another embodiment, an energy collection system comprises a main body formed from a decorative material substantially blended in visual appearance in respect of a mounting structure, the main body having a first surface and a second surface; a photovoltaic cell disposed in the main body for capturing light energy, the first surface of the main body having at least one window formed therein to minimize a view of the photovoltaic cell to maximize an aesthetic appeal thereof; and an adhesive material disposed on the second surface of the main body.

### BRIEF DESCRIPTION OF THE DRAWINGS

The objects and advantages of the present invention will become readily manifest to those skilled in the art from reading the following description of a preferred embodiment of the invention when considered in the light of the accompanying drawings, in which:

FIG. 1 is a front elevational view of a keyless entry system according to an embodiment of the invention including a housing containing operative parts of the keyless entry system;

FIG. 2 is a rear elevational view of the housing illustrated in FIG. 1;

FIG. 3 is a rear elevational view of the housing illustrated in FIG. 2 with the back panel removed to expose the internal operational components thereof in a normal static locked position with the remotely actuated locking mechanism in a keyless locked position;

FIG. 4 is a view similar to FIG. 3 with the remotely actuated locking mechanism in a keyless unlocked position;

FIG. 5 is a view similar to FIG. 4 with the key actuated locking mechanism in a key locked position;

FIG. 6 is a view similar to FIG. 4 with the key actuated locking mechanism in a key unlocked position;

FIG. 7 is a sectional view of the housing illustrated in FIG. 2, taken along line 7-7 and showing the plug disengaged from the housing;

FIG. 8 is a fragmentary sectional view of the housing illustrated in FIG. 2, showing the plug engaged with the housing;

FIG. 9 is a schematic diagram showing an exemplary accessory system according to an embodiment of the present invention;

FIG. 10 is a perspective view of a decorative element incorporating a photovoltaic cell according to an embodiment of the invention;

FIG. 11 is a perspective view of a decorative element incorporating a photovoltaic cell according to another embodiment of the invention;

FIG. 12 is a schematic diagram showing a self energizing remote locking system according to another embodiment of the present invention;

FIG. 13 is a schematic diagram showing a locking system according to another embodiment of the present invention; and

FIG. 14 is a perspective view of an energy collection panel system according to an embodiment of the invention.

### DETAILED DESCRIPTION OF THE PREFERRED EMBODIMENT

The objects and advantages of the present invention will become readily manifest to those skilled in the art from reading the following description of a preferred embodiment of the invention when considered in the light of the accompanying drawing. In respect of the method of operation disclosed, the steps presented are exemplary in nature, and thus, the order of the steps is not necessary or critical.

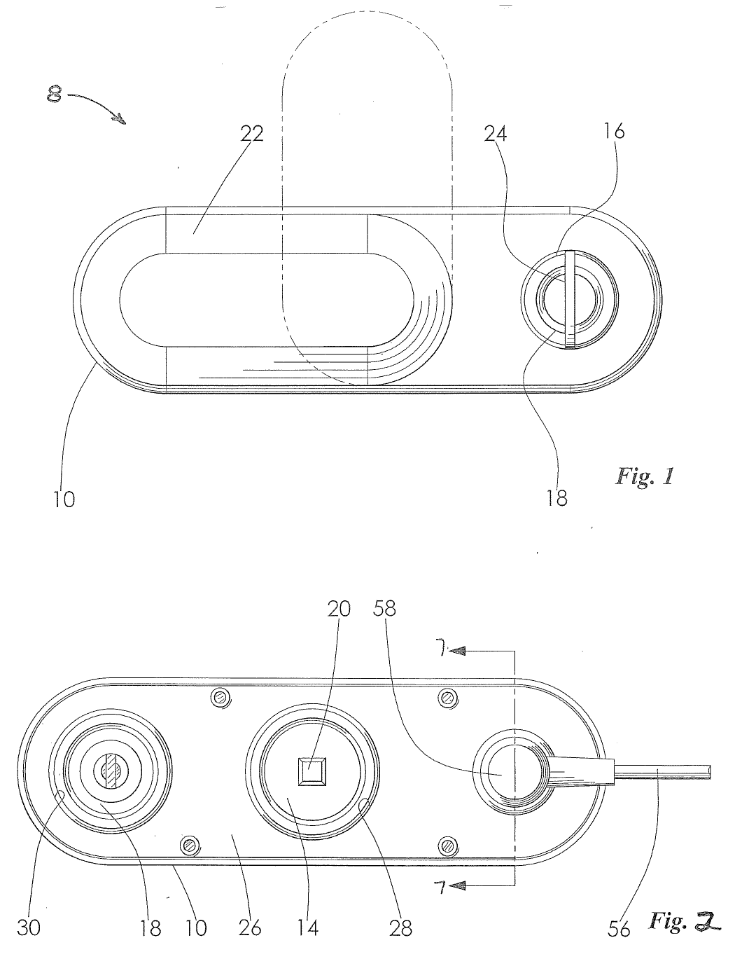

For exemplary purposes, the invention will be initially described for use with a keyless entry system accessory 8. However, it is understood that the invention can be used with other accessory systems such as signal lighting, general lighting, cigarette lighter adapters, portable storage devices, tool boxes, and the like, for example. Other entry systems and locking mechanisms can also be used with the invention without departing from the scope and spirit thereof. FIG. 1 illustrates the keyless entry system 8 which includes a housing 10. The housing 10 can be formed from plastic, metal, or other suitable material. Additionally, the housing 10 may be provided with means for attachment (not shown) of the housing to an associated structure such as a door, trunk, camper entry, etc. A front portion of the housing 10 is provided with an aperture 12 for receiving a latch assembly 14, and an aperture 16 for receiving a key actuated locking mechanism 18, as more clearly shown in FIGS. 2-6.

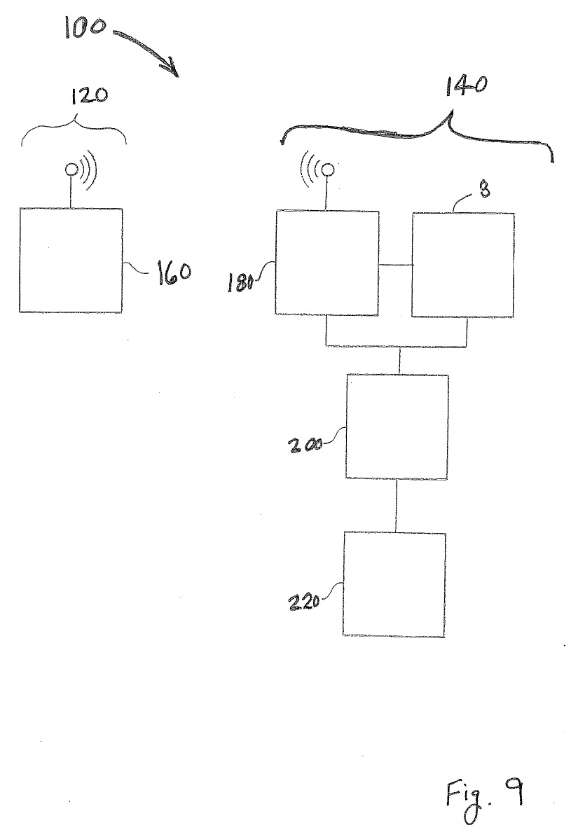

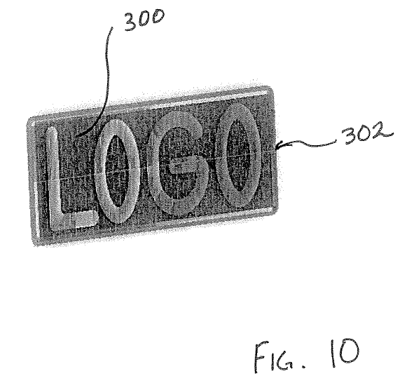

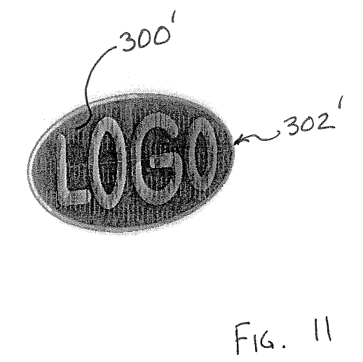

The housing 10 is provided with a backing plate or cover 26 which may be secured to the housing 10 by threaded fasteners (not shown) or other suitable fastening means, as illustrated in FIG. 2. An electrical lead 56 is attached to an electrical conductor 58 at a first end. A second end of the electrical lead 56 is attached to an energy storing device 200, discussed in more detail below in respect of FIG. 9. It is understood that the energy storing device 200 can be contained in the housing 10 or attached thereto, thereby eliminating or minimizing a requirement for electrical wiring and the like. The electrical lead 56 and electrical conductor 58 supply electrical power to the keyless entry system accessory 8 from the energy storing device 200.

As more clearly shown in FIG. 7, the electrical conductor 58 includes a pin 60 and a pair of terminals 62 extending outwardly therefrom. The pin 60 is formed from a non-conductive material such as plastic, for example. The terminals 62 are formed from a conductive material such as metal, for example. The housing 10 includes an aperture 64 formed therein adapted to receive the electrical conductor 58.

A terminal assembly 66 is disposed in the aperture 64 and includes a pair of conductive terminals 68. In the embodiment shown, the terminals 68 are substantially J-shaped. The terminals 68 abut one another to short circuit an electrical path. When the electrical conductor 58 is inserted into the aperture 64 formed in the housing 10, the pin 60 causes the pair of conductive terminals 68 to be moved laterally outwardly from one another, as shown in FIG. 8, thus forming a complete circuit. The insertion of the pin 60 between the terminals 68 causes outer edges 70 of the terminals 68 to contact the conductive terminals 62 of the electrical conductor 58 to create a conductive path. It is understood that other electrical conductors and terminal assemblies can be used as desired.

The latch assembly 14 includes a centrally disposed shaft 20, the outermost end of which is attached to a handle 22. The handle 22 is operative to rotate the shaft 20 about the longitudinal axis thereof from the normal position shown in FIG. 1 in full lines, to the position illustrated in phantom lines, to actuate a latch (not shown) of an associated entry system.

The key actuated locking mechanism 18 is adapted to receive a key 24 for selectively moving the locking mechanism 18 to a locking position and an unlocking position. While the locking mechanism 18 may be of a variety of types, favorable results have been obtained using a self centering type locking mechanism. The self centering type mechanism normally maintains the key receiving slot and the associated key 24 in a static centered position, as illustrated in FIG. 1. Spring means (not shown) may be employed to urge the mechanism 18 to the static position when any rotational torque being applied to the key 24 is released. The locking mechanism 18 is provided with an integral radially outwardly extending arm 32 which terminates at an end portion 34, as illustrated in FIGS. 3-6.

The backing plate or cover 26 is provided with an aperture 28 which receives the latch assembly 14 and the associated shaft 20 therein. An aperture 30 is formed in the backing plate or cover 26 spaced from the aperture 28 for receiving the locking mechanism 18.

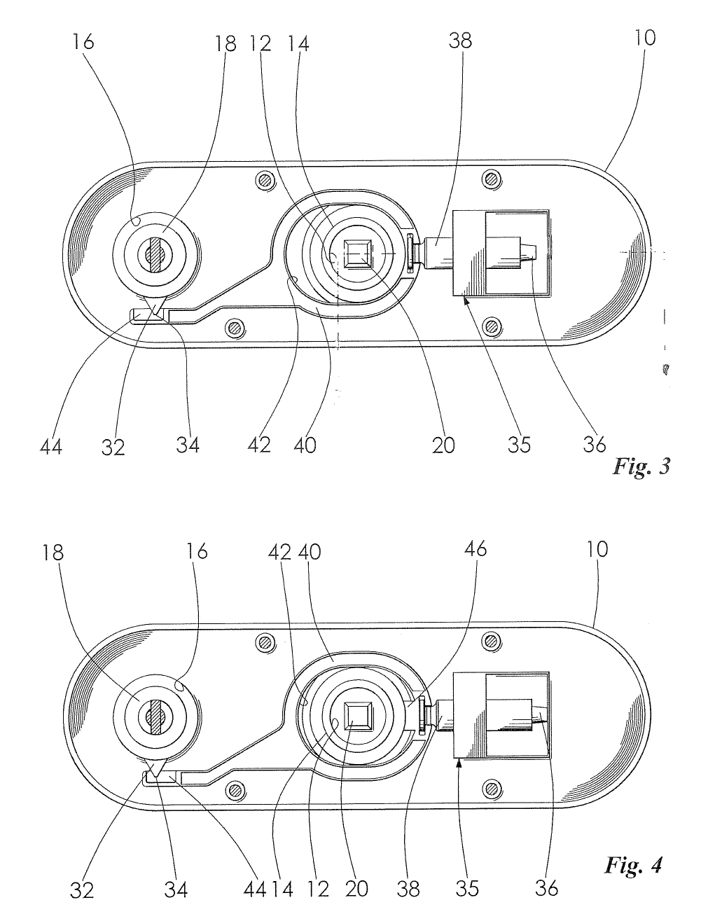

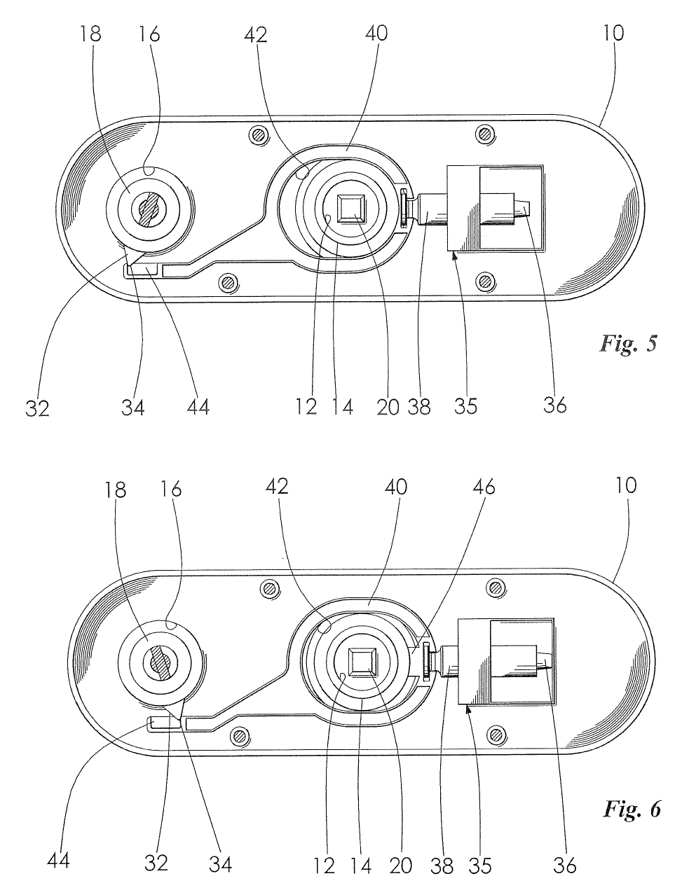

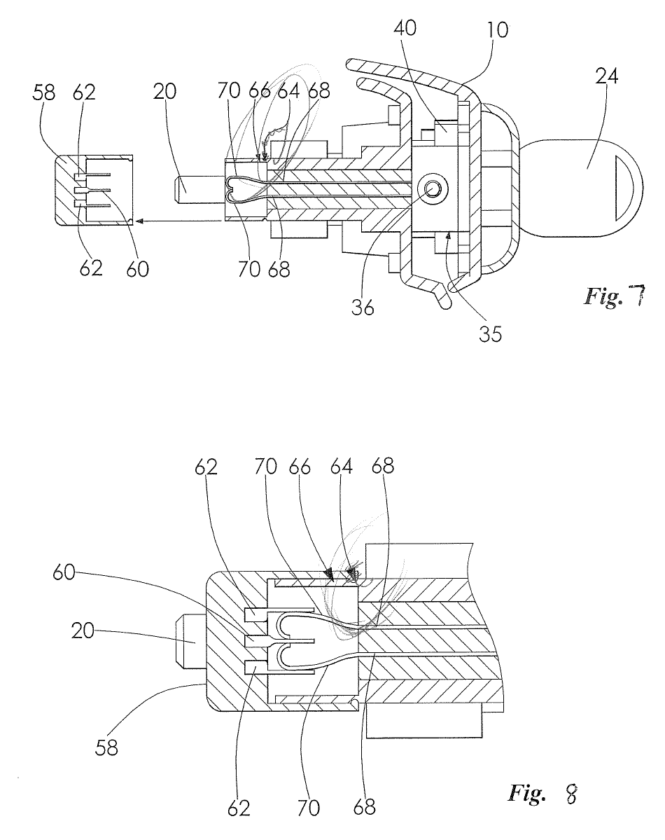

In FIGS. 3-6, a remotely actuated power locking mechanism 35 is shown disposed in the housing 10. The power locking mechanism 35 includes an actuator 36 having an associated armature 38. The actuator 36 can be any conventional operator such as a solenoid, for example. Upon energization of the actuator 36, the armature 38 is caused to be moved to one of an extended position as shown in FIGS. 3 and 5, or a retracted position as shown in FIGS. 4 and 6.

An elongate sliding member 40 having a central aperture 42 has a first end coupled to the armature 38 of the actuator 36. A second end is provided with a slot 44 for receiving the end portion 34 of the arm 32 of the locking mechanism 18. A radially inwardly extending tab or detent 46 is formed on the sliding member 40. The tab 46 is adapted to engage an aperture 48 formed in the shaft 20 of the latch mechanism 14. The aperture 48 can be a slot, hole, groove, or recess, as desired. It is understood that the tab 46 could be formed separately from the sliding member 40 without departing from the scope or spirit of the invention.

Although the sliding member 40 is shown with a central aperture 42 having a generally circular shape, it is understood that other shapes and configurations can be used. The function of the sliding member 40 is to mechanically interconnect the remotely actuated power locking mechanism 35 and the key actuated locking mechanism 18 to selectively permit or militate against the rotation of the shaft 20 of the latch assembly 14.

FIG. 9 shows a locking system 100 according to an embodiment of the invention. As used herein, locking as part of locking system is meant to include locking, latching, unlocking, unlatching, militating against opening, facilitating opening, and the like. The locking system 100 includes a transmitting portion 120 and a receiving portion 140. The transmitting portion 120 includes a transmitter 160 adapted to generate and transmit a signal. Any conventional transmitting device can be used as the transmitter 160 such as a key fob or other transmitter, for example. The transmitter 160 can be powered by any conventional means such as by an internal battery (not shown) or wired to an external source of electrical power (not shown), for example. It is understood that the signal can be generated and transmitted manually by depressing a button, or automatically at a desired time or occurrence of an event without departing from the scope and spirit of the invention.

The receiving portion 140 of the locking system 100 includes a receiver 180 adapted to receive a signal. Energy is provided to the receiver 180 by the energy storing device 200. In the embodiment shown, the energy storing device 200 stores electrical energy in a battery, capacitor, and the like. The receiver 180 can use the same type or a different type of energy than that stored by the energy storing device 200. Where the energy type is different, the required type of energy to be used by the receiver 180 can be converted within the receiver 180 or the energy storing device 200, as desired. For example, if the energy storing device 200 stores electrical energy and the receiver 180 requires pneumatic energy, the electrical energy can be converted to pneumatic energy in the energy storing device 200 or the receiver 180.

An energy capture device 220 is in communication with the energy storing device 200 to transfer energy captured by the energy capture device 220 to the energy storing device 200. In the embodiment shown, the energy capture device 220 is a solar cell or photovoltaic cell adapted to capture solar energy or light energy. The solar cell or photovoltaic cell can be disposed on an outer surface of a vehicle or other location exposed to solar energy or light energy as desired.

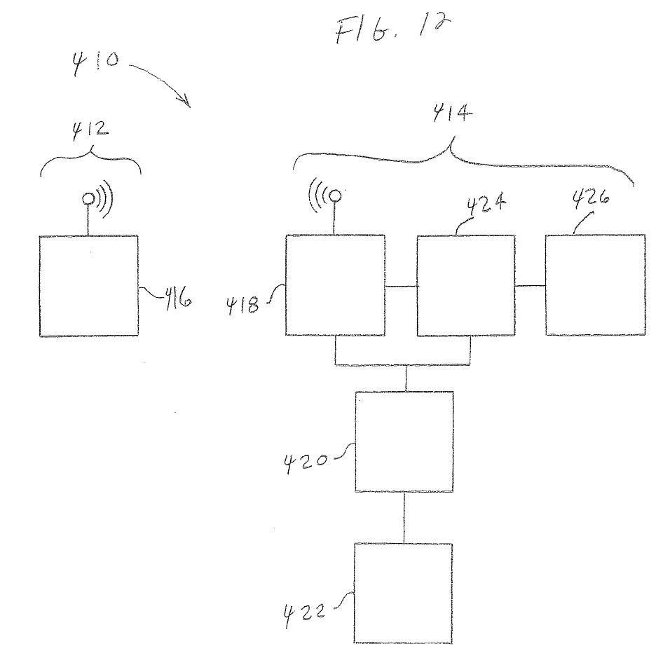

FIGS. 10 and 11 illustrate an embodiment of the invention where a solar cell or plurality of solar cells 300 is incorporated into a decorative element 302. As used herein, solar cell also means a photovoltaic cell adapted to receive solar energy or light energy. In the embodiment shown, the solar cell or photovoltaic cell 300 is provided as a background for a logo. The logo can be an automobile manufacturer logo or an aftermarket vehicle accessory manufacturer logo, for example. The decorative element 302 can be other decorative elements as desired. It is understood that other types of energy can be captured by the energy capture device 220. It is further understood that the energy capture device 220 and the energy storing device 200 can be provided as a unitary structure, wherein the energy is captured and stored in a single device, the energy capture device 220 can be located remotely of the energy storing device 200, or the energy capture device 220 can be directly connected to the energy storing device 220.

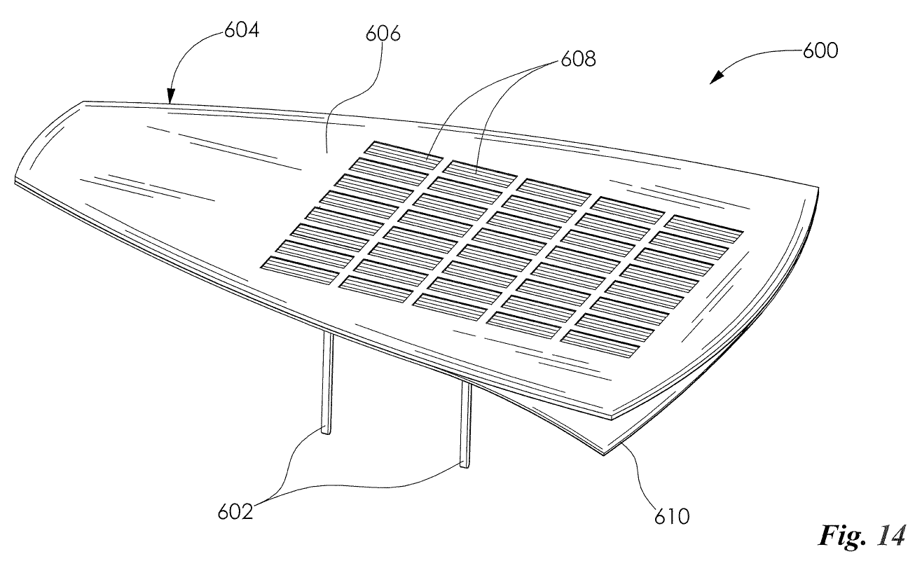

FIG. 14 shows a solar panel system 600 according to another embodiment of the invention. As used herein, solar cell also means a photovoltaic cell adapted to receive solar energy or light energy. The solar panel system 600 can be used as the energy capture device 220 in communication with the energy storing device 200, or in other electrical systems, as desired.

The solar panel system 600 includes a pair of conductive tabs 602 functioning as electrical leads adapted to be connected to the energy storing device 200. It is understood that the solar panel system 600 and the energy storing device 200 can be provided as a unitary structure, wherein the energy is captured and stored in a single device as desired. The conductive tabs 602 are adapted to be in electrical communication with an accessory system or other user of electrical energy. It is also understood that the solar panel system 600 can be located remotely of the energy storing device 200.

In the embodiment shown, the solar panel system 600 includes a decorative main body 604 having a generally triangular shape. It is understood that other shapes and configurations can be used as desired. For example, the main body 604 can be adapted to substantially blend or contrast with an exterior surface (not shown) of a mounting structure (not shown), such as an outer surface of a vehicle which is exposed to solar energy or light energy, for example. Additionally, the main body 604 can be disposed in or joined with a pre-existing decorative element (not shown). The main body 604 can be formed from any suitable material, such as an aesthetically pleasing decorative plastic material, for example.

The main body 604 includes a solar cell or photovoltaic cell 608 adapted to capture solar energy or light energy. It is understood that a plurality of solar cells or photovoltaic cells 608 can be used if desired. The solar cell or photovoltaic cell 608 is in electrical communication with the tabs 602. In the embodiment shown, a first surface 606 of the main body includes a plurality of transparent windows formed therein to facilitate a capturing of solar energy by at least a portion of the solar cell 608. In the embodiment shown, the windows are substantially rectangular in shape. However, any shape of windows can be used as desired such as circular, triangular, irregular, and the like, for example. Additionally, the windows can be formed in any desired pattern such as a dot pattern, an aesthetically pleasing pattern such as waving lines, regular patterns such as the embodiment shown, and the like, for example. The first surface 606 of the main body 604 can also be at least partially formed from any conventional transparent, semi-transparent, or translucent material, for example, which permits a desired amount of solar energy or light energy to be received by the solar cell or photovoltaic cell 608. Additionally, at least one aperture can be formed in the first surface 606 in any shape or configuration as desired to permit the desired amount of solar energy or light energy to be received by the solar cell 608. Accordingly, the solar cell 608 is at least partially camouflaged, concealed, hidden, obscured, or a view thereof minimized in order to maximize an aesthetic appeal thereof.

A second surface (not shown) of the main body 604 includes an adhesive material disposed thereon. The adhesive material can be a double sided tape or other suitable adhesive material which facilitates an adherence of the solar panel system 600 to the mounting structure. In order to protect the adhesive material, a paper backing 610 can be applied to or included therewith, which can be removed prior to installation of the solar panel system 600 on the mounting structure.

To assemble the solar panel system 600 for use, the paper backing 610 is removed to expose the adhesive material 610. The tabs 602 are electrically connected as desired, and the solar panel system 600 is disposed on the mounting structure.

In operation, solar energy or light energy impinges on the solar cell or photovoltaic cell 608. The solar energy or light energy is captured by the solar cells or photovoltaic cells 608 and transferred to the energy storing device 200. Although any desired voltage and current can be provided, 6 volts and 60 milliamps have been attained for the embodiment shown. A size, configuration, and amount of solar energy or light energy permitted to impinge upon the solar cell or photovoltaic cell 608 can be adjusted as desired to increase or decrease the voltage and current. The energy captured by the solar panel system 600 can also be converted to another energy type prior to, during, or after transfer to the energy storing device. For example, if electrical energy is being transferred from the solar panel system 600, the energy can be converted to pneumatic energy for storage in the energy storing device. It is understood that additional structure (not shown) such as a generator, motor, pump, and the like may be required to facilitate the conversion of the energy from one type to another.

The keyless entry system 8 is in communication with and operated by the receiver 180. Energy is provided to the keyless entry system 8 by the energy storing device 200. It is understood that the keyless entry system 8 can use the same type or a different type of energy than that stored by the energy storing device 200. The energy types can include mechanical, hydraulic, pneumatic, centrifugal, electrical, and the like. Where the energy type is different, the type of energy to be used by the keyless entry system 8 can be converted within the actuator 240 or the energy storing device 200 as described above for the receiver 180.

In operation, the locked position of the keyless entry system of the invention is illustrated in FIG. 3. As illustrated, the shaft 20 is prevented from rotation due to the insertion of the tab 46 into the aperture 48 of the shaft 20. While the keyless entry system is in a locked position a rotation of the shaft 20 of the handle 22 is militated against.

To unlock the keyless entry system, the tab 46 is moved outwardly to disengage from the aperture 48 of the shaft 20. The tab 46 may be moved outwardly by selecting one of two alternatives. One of the alternatives involves operation of the actuator 36 to cause the armature 38 and the sliding member 40 to move from the position illustrated in FIG. 3 to the position illustrated in FIG. 4. Such movement of the sliding member 40 permits the tab 46 to disengage from the aperture 48 of the shaft 20, thus enabling the handle 22 to effect rotation of the shaft 20.

The operation of the actuator 36 may be typically achieved by the receiver 180 which will, upon receiving an appropriate signal from the transmitter 160 such as a key fob, cause operation of the actuator 36. Such systems are commercially available, for example, from Maxim Integrated Products, Inc., Sunnyvale, Calif. 94086.

To provide electrical energy to the keyless entry system 8, light energy impinges on the energy capture device 220. The energy is captured by the energy capture device 220 and transferred to the energy storing device 200. It is understood that energy transfer may not be necessary where the energy storing device 200 and the energy capture device 220 are a unitary structure. The energy captured by the energy capture device 220 can also be converted to another energy type prior to, during, or after transfer to the energy storing device 200. For example, if electrical energy is being transferred from the energy capture device 220, the energy can be converted to mechanical energy for storage in the energy storing device 200. It is understood that additional structure such as a generator, motor, pump, and the like may be required to facilitate the conversion of the energy from one type to another.

The energy stored in the energy storing device 200 is used to power the receiver 180 and the keyless entry system 8. Thus, when it is desired to operate the keyless entry system 8, the transmitter 160 is caused to transmit a signal, which is received by the receiver 180. The receiver 180 then causes a desired actuation of the keyless entry system 8. Therefore, the keyless entry system 8 can be locked or latched and unlocked or unlatched as desired with the transmitter 160 located remotely of the receiving portion 140 of the locking system 100. It is desirable that the energy storing device 200 is capable of storing sufficient energy to power the receiver 180 and keyless entry system 8 through numerous cycles to account for periods when power is not captured by the energy capture device 220 for any reason. Such periods can occur at night, during storms, during overcast days, when a vehicle is parked in or operating in areas without light, and the like.

The locking system 100 can include a receiving portion 140 that is a self contained system for storing energy to in turn lock/latch or unlock/unlatch the keyless entry system 8. When used for a vehicle, for example, the need for a wiring harness is eliminated for the locking system 100, thus minimizing a cost and complexity of the locking system 100.

The energy storing device 200 can also be used to provide power to numerous other accessories (not shown) such as signal lighting, general lighting, cigarette lighter adapters, and the like, for example. The additional accessories are provided with electrical connections to the energy storing device. Thus, the need for the wiring harness to supply electrical energy to these accessories is also eliminated. Therefore, a self-contained, self powered, simple and economical accessory system can be provided as original equipment or as an aftermarket accessory, wherein a requirement for external wiring and the like is eliminated. Aesthetics of the vehicle are preserved, a complexity of installation is minimized, and costs of the accessory system and installation are also minimized.

Another alternative, as illustrated in FIGS. 5 and 6, involves actuation of the locking mechanism 18 by the key 24. Rotation of the key 24 causes movement of the radially extending arm 32. As the arm 32 is caused to move, the terminal end 34 abuts an end wall of the slot 44 of the sliding member 40 to cause the sliding member 40 to move from the position shown in FIG. 5 to the position shown in FIG. 6, thus causing the tab 46 to disengage from the aperture 48.

FIG. 5 illustrates the locked condition of the system wherein the locking mechanism 18 has been rotated to position the terminal end 34 and the arm 32 against one end wall of the slot 44, which causes the tab 46 to move into engagement with the aperture 48 of the shaft 20.

Other embodiments of a remote keyless entry system are illustrated in commonly owned U.S. patent application Ser. No. 11/412,571, hereby incorporated herein by reference in its entirety.

The invention has been found to be particularly useful for truck caps, tonneau covers, camper tops, and the like where providing a wiring harness is difficult, time consuming, and not aesthetically pleasing.

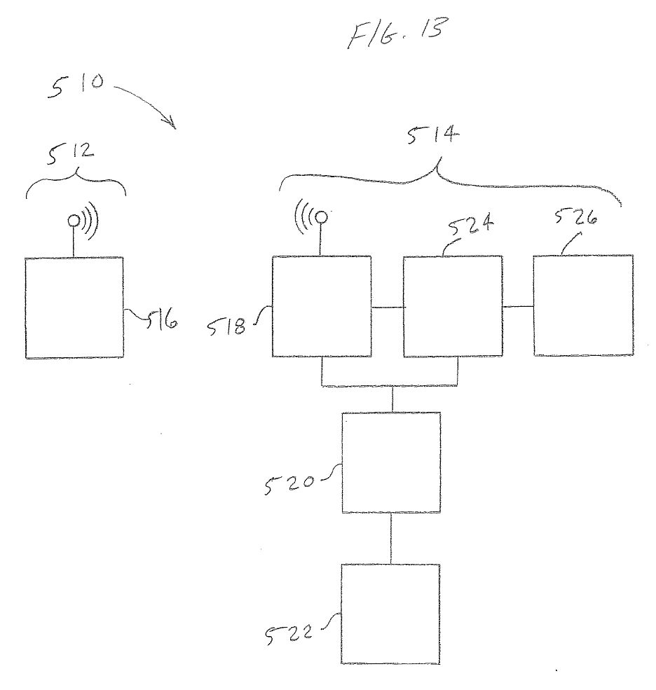

FIG. 12 shows a self energizing remote locking system 410 according to an embodiment of the invention. The locking system 410 includes a transmitting portion 412 and a receiving portion 414. The transmitting portion 412 includes a transmitter 416 adapted to generate and transmit a signal. Any conventional transmitting device can be used as the transmitter 416 such as a key fob or other transmitter, for example. The transmitter 416 can be powered by any conventional means such as by an internal battery (not shown) or wired to an external source of electrical power (not shown), for example. It is understood that the signal can be generated and transmitted manually by depressing a button, or automatically at a desired time or occurrence of an event without departing from the scope and spirit of the invention.

The receiving portion 414 of the locking system 410 includes a receiver 418 adapted to receive a signal. Energy is provided to the receiver 418 by an energy storing device 420. The energy storing device 420 can store energy in any form as desired such as mechanical, hydraulic, pneumatic, centrifugal, electrical, and the like, for example. Mechanical energy can be stored in a linearly compressed spring or spirally loaded spring, for example. Electrical energy can be stored in a battery, a capacitor, and the like. The receiver 418 can use the same type or a different type of energy than that stored by the energy storing device 420. Where the energy type is different, the required type of energy to be used by the receiver 418 can be converted within the receiver 418 or the energy storing device 420, as desired. For example, if the energy storing device 420 stores energy pneumatically and the receiver 418 requires electrical energy, the pneumatic energy can be converted to electrical energy in the energy storing device 420 or the receiver 418.

An energy capture device 422 is in communication with the energy storing device 420 to transfer energy captured by the energy capture device 422 to the energy storing device 420. In the embodiment shown, the energy capture device 422 is adapted to capture energy of motion such as energy required for linear, rotary, oscillating, and vibrating motion, for example. It is understood that other types of energy can be captured by the energy capture device 422. It is further understood that the energy capture device 422 and the energy storing device 420 can be provided as a unitary structure, wherein the energy is captured and stored in a single device. Such combined devices can include a spring, a hydraulic cylinder, a pneumatic cylinder, and the like, for example. Typically, the energy capture device 422 captures energy used to close or otherwise move a structure (not shown) to be locked such as a door or a gate, for example. The energy used to close or move the structure may be provided by a user or other source such as wind, running water, and the like.

An actuator 424 is in communication with and operated by the receiver 418. Energy is provided to the actuator 424 by the energy storing device 420. The actuator 424 can use the same type or a different type of energy than that stored by the energy storing device 420. The energy types can include mechanical, hydraulic, pneumatic, centrifugal, electrical, and the like. Where the energy type is different, the type of energy to be used by the actuator 424 can be converted within the actuator 424 or the energy storing device 420 as described above for the receiver 418.

A locking device 426 is in communication with the actuator 424. The locking device 426 can be any conventional locking device type such as a linear type, a tumbler type, a rotary type, and the like, for example. The locking device 426 is adapted to be locked or latched and unlocked or unlatched by the actuator 424. It is understood that the locking device 426 and the actuator 424 can be combined into a single structure.

In operation, energy is applied to the structure to be locked. The energy applied can be used to close the structure such as close a door, or to move the structure from one position to another such as move a window from one intermediate position to another. The energy is typically energy of motion such as linear, rotary, oscillating, and vibrating motion, for example. The energy applied is captured by the energy capture device 422 and transferred to the energy storing device 420. It is understood that energy transfer may not be necessary where the energy storing device 420 and the energy capture device 422 are a unitary structure. The energy captured by the energy capture device 422 can also be converted to another energy type prior to, during, or after transfer to the energy storing device 420. For example, if rotary motion of a door is captured in a spirally loaded spring, the energy captured in the spring can be converted to electrical energy for storage in a battery. It is understood that additional structure such as a generator, motor, and the like may be required to facilitate the conversion of the energy from one type to another.

The energy stored in the energy storing device 420 is used to power the receiver 418 and the actuator 424. Thus, when it is desired to operate the locking device 426, the transmitter 416 is caused to transmit a signal, which is received by the receiver 418. The receiver 418 then causes actuation of the actuator 424 to result in a desired motion of the locking device 426. Therefore, the locking device 426 can be locked or latched and unlocked or unlatched as desired with the transmitter 416 located remotely of the receiving portion 414 of the locking system 410. It is desirable that the energy storing device 420 is capable of storing sufficient energy to power the receiver 418 and actuator 424 through several cycles to account for periods when power is not captured by the energy capture device 422 for any reason.

The locking system 410 can include a receiving portion 414 that is a self contained system for storing energy from the closure of the structure being locked to in turn lock/latch or unlock/unlatch the structure. The energy stored can be created in a number of ways including linear, rotary, oscillating, or vibrating motion that generates an electrical charge; and linear, rotary, oscillating, or vibrating motion that is converted to mechanical, hydraulic, pneumatic, or centrifugal energy.

It may be desirable to design a low energy locking device 426 to minimize the amount of energy required to lock or unlock the locking device 426. The design may include minimizing the amount of friction within the components of the locking device 426, for example.

FIG. 13 shows a locking system 510 according to another embodiment of the invention. The locking system 510 includes a transmitting portion 512 and a receiving portion 514. The transmitting portion 512 includes a transmitter 516 adapted to generate and transmit a signal. Any conventional transmitting device can be used as the transmitter 516 such as a key fob or other transmitter, for example. The transmitter 516 can be powered by any conventional means such as by an internal battery (not shown) or wired to an external source of electrical power (not shown), for example. It is understood that the signal can be generated and transmitted manually by depressing a button, or automatically at a desired time or occurrence of an event without departing from the scope and spirit of the invention.

The receiving portion 514 of the locking system 510 includes a receiver 518 adapted to receive a signal. Energy is provided to the receiver 518 by an energy storing device 520. In the embodiment shown, the energy storing device 520 stores electrical energy in a battery, capacitor, or the like. The receiver 518 can use the same type or a different type of energy than that stored by the energy storing device 520. Where the energy type is different, the required type of energy to be used by the receiver 518 can be converted within the receiver 518 or the energy storing device 520, as desired. For example, if the energy storing device 520 stores electrical energy and the receiver 518 requires pneumatic energy, the electrical energy can be converted to pneumatic energy in the energy storing device 520 or the receiver 518.

An energy capture device 522 is in communication with the energy storing device 520 to transfer energy captured by the energy capture device 522 to the energy storing device 520. In the embodiment shown, the energy capture device 522 is a solar cell adapted to capture solar energy. It is understood that other types of energy can be captured by the energy capture device 522. It is further understood that the energy capture device 522 and the energy storing device 520 can be provided as a unitary structure wherein the energy is captured and stored in a single device.

An actuator 524 is in communication with and operated by the receiver 518. Energy is provided to the actuator 524 by the energy storing device 520. The actuator 524 can use the same type or a different type of energy than that stored by the energy storing device 520. The energy types can include mechanical, hydraulic, pneumatic, centrifugal, electrical, and the like. Where the energy type is different, the type of energy to be used by the actuator 524 can be converted within the actuator 524 or the energy storing device 520 as described above for the receiver 518.

A locking device 526 is in communication with the actuator 524. The locking device 526 can be any conventional locking device type such as a linear type, a tumbler type, a rotary type, and the like, for example. The locking device 526 is adapted to be locked or latched and unlocked or unlatched by the actuator 524. It is understood that the locking device 526 and the actuator 524 can be combined into a single structure.

In operation, solar energy impinges on the energy capture device 522. The energy is captured by the energy capture device 522 and transferred to the energy storing device 520. It is understood that energy transfer may not be necessary where the energy storing device 520 and the energy capture device 522 are a unitary structure. The energy captured by the energy capture device 522 can also be converted to another energy type prior to, during, or after transfer to the energy storing device 520. For example, if electrical energy is being transferred from the energy capture device 522, the energy can be converted to pneumatic energy for storage in the energy storing device 520. It is understood that additional structure such as a generator, motor, pump, and the like may be required to facilitate the conversion of the energy from one type to another.

The energy stored in the energy storing device 520 is used to power the receiver 518 and the actuator 524. Thus, when it is desired to operate the locking device 526, the transmitter 516 is caused to transmit a signal, which is received by the receiver 518. The receiver 518 then causes actuation of the actuator 524 to result in a desired motion of the locking device 526. Therefore, the locking device 526 can be locked or latched and unlocked or unlatched as desired with the transmitter 516 located remotely of the receiving portion 514 of the locking system 510. It is desirable that the energy storing device 520 is capable of storing sufficient energy to power the receiver 518 and actuator 524 through numerous cycles to account for periods when power is not captured by the energy capture device 522 for any reason. Such periods can occur at night, during storms, during overcast days, when a vehicle is parked in or operating in areas with out sunlight, and the like.

The locking system 510 can include a receiving portion 514 that is a self contained system for storing solar energy to in turn lock/latch or unlock/unlatch the locking device 526. When used for a vehicle, for example, the need for a wiring harness is eliminated for the locking system 510, thus minimizing a cost and complexity of the locking system 510.

It may be desirable to design a low energy locking device 526 to minimize the amount of energy required to lock or unlock the locking device 526. The design may include minimizing the amount of friction within the components of the locking device 526, for example.

From the foregoing description, one ordinarily skilled in the art can easily ascertain the essential characteristics of this invention and, without departing from the spirit and scope thereof, can make various changes and modifications to the invention to adapt it to various usages and conditions.

What is claimed is:

1. An energy collection system comprising:
a main body having a first surface and a second surface;
a photovoltaic cell disposed in the main body for capturing light energy, the main body cooperating with the photovoltaic cell to maximize an aesthetic appeal of the energy collection system; and
an adhesive material disposed on the second surface of the main body.

2. The system according to claim 1, wherein the first surface of the main body includes a plurality of apertures formed therein to permit light energy to be received by the photovoltaic cell.

3. The system according to claim 1, wherein the first surface of the main body includes at least one window to permit light energy to be received by the photovoltaic cell.

4. The system according to claim 3, wherein the at least one window is formed from at least one of a transparent material, a semi-transparent material, and a translucent material.

5. The system according to claim 3, wherein the at least one window has a rectangular shape.

6. The system according to claim 3, wherein the at least one window has a circular shape.

7. The system according to claim 3, wherein the at least one window has an irregular shape.

8. The system according to claim 1, wherein the adhesive material is a double sided tape.

9. An energy collection system comprising:
a main body having a first surface and a second surface;
a photovoltaic cell disposed in the main body for capturing light energy, the first surface of the main body having at least one window formed therein to minimize a view of the photovoltaic cell and maximize an aesthetic appeal of the energy collection system; and
an adhesive material disposed on the second surface of the main body.

10. The system according to claim 9, wherein the at least one window includes an aperture formed therein.

11. The system according to claim 9, wherein the at least one window is formed from at least one of a transparent material, a semi-transparent material, and a translucent material.

12. The system according to claim 9, wherein the at least one window has a rectangular shape.

13. The system according to claim 9, wherein the at least one window has a circular shape

14. The system according to claim 9, wherein the at least one window has an irregular shape.

15. The system according to claim 9, wherein the adhesive material is a double sided tape.

16. The system according to claim 9, wherein the main body is substantially blended in visual appearance in respect of a mounting structure.

17. An energy collection system comprising:
a main body formed from a decorative material substantially blended in visual appearance in respect of a mounting structure, the main body having a first surface and a second surface;
a photovoltaic cell disposed in the main body for capturing light energy, the first surface of the main body having at least one window formed therein to minimize a view of the photovoltaic cell to maximize an aesthetic appeal thereof; and
an adhesive material disposed on the second surface of the main body.

18. The system according to claim 17, wherein the at least one window includes an aperture formed therein.

19. The system according to claim 17, wherein the at least one window is formed from at least one of a transparent material, a semi-transparent material, and a translucent material.

20. The system according to claim 17, wherein the adhesive material is a double sided tape.
